(19) United States
(12) Patent Application Publication
(10) Pub. No.: US 2026/0145421 A1
(43) Pub. Date: May 28, 2026

(54) FLEXIBLE BOARD, LIQUID JET HEAD, AND LIQUID JET RECORDING APPARATUS

(71) Applicant: SII Printek Inc., Chiba-shi (JP)

(72) Inventor: Yukihiro SAGA, Chiba-shi (JP)

(21) Appl. No.: 19/397,239

(22) Filed: Nov. 21, 2025

(30) Foreign Application Priority Data
Nov. 28, 2024 (JP) 2024-207555

(51) Int. Cl. B41J 2/045; B41J 2/14; H05K 1/02; H05K 1/11

(52) U.S. Cl. CPC B41J 2/04548; B41J 2/04581; B41J 2/14201; H05K 1/0281; H05K 1/118; B41J 2002/14491; H05K 2201/2009

(57) ABSTRACT

A flexible board and so on the manufacturing cost of which can be reduced, and the reliability of which can be improved are provided. The flexible board according to an embodiment of the present disclosure is a flexible board configured to transmit electric signals to be applied to a liquid jet head having a plurality of nozzles, and includes a terminal section disposed in an end region on a board surface, and including a single electrode terminal or a plurality of electrode terminals as a part to electrically be coupled to another member. The electrode terminal is disposed in the end region at a distance from an outer shape position of the board surface via a non-electrode region.

### RELATED APPLICATIONS

This application claims priority to Japanese Patent application No. JP2024-207555, filed on Nov. 28, 2024, the entire content of which is incorporated herein by reference.

### BACKGROUND OF THE INVENTION

### 1. Field of the Invention

The present disclosure relates to a flexible board, a liquid jet head, and a liquid jet recording apparatus.

### 2. Description of the Related Art

Liquid jet recording apparatuses equipped with liquid jet heads are used in a variety of fields, and a variety of types of liquid jet heads have been developed.

In such liquid jet heads, in general, it is required to reduce the manufacturing cost and to improve the reliability.

It is desirable to provide a flexible board, a liquid jet head, and a liquid jet recording apparatus, the manufacturing cost of which can be reduced, and the reliability of which can be improved.

### SUMMARY OF THE INVENTION

The flexible board according to an embodiment of the present disclosure is a flexible board configured to transmit electric signals to be applied to a liquid jet head having a plurality of nozzles, and includes a terminal section disposed in an end region on a board surface, and including a single electrode terminal or a plurality of electrode terminals as a part to electrically be coupled to another member. The electrode terminal is disposed in the end region at a distance from an outer shape position of the board surface via a non-electrode region.

The liquid jet head according to an embodiment of the present disclosure includes the flexible board according to the embodiment of the present disclosure described above, and a jet section which is configured to jet the liquid based on the electric signals transmitted from the flexible board, and which includes a plurality of nozzles.

A liquid jet recording apparatus according to an embodiment of the present disclosure includes the liquid jet head according to the embodiment of the present disclosure described above.

According to the flexible board, the liquid jet head, and the liquid jet recording apparatus related to an embodiment of the present disclosure, it becomes possible to improve the reliability while reducing the manufacturing cost.

### BRIEF DESCRIPTION OF THE DRAWINGS

FIG. 1 is a block diagram showing an outline configuration example of a liquid jet apparatus according to an embodiment of the present disclosure.

FIG. 2 is a perspective view schematically showing an outline configuration example of a liquid jet head shown in FIG. 1.

FIG. 3 is a cross-sectional view schematically showing a configuration example of the liquid jet head shown in FIG. 2.

FIG. 4 is a plan view schematically showing an outline configuration example of the flexible board shown in FIG. 2 and FIG. 3.

FIG. 5 is a cross-sectional view schematically showing an outline configuration example of the flexible board shown in FIG. 4.

FIG. 6 is a plan view schematically showing a part of the flexible board shown in FIG. 4 in an enlarged manner.

FIG. 7 is a plan view schematically showing a configuration example of a flexible board according to a comparative example.

FIG. 8 is a plan view schematically showing an outline configuration example of a flexible board according to a modified example.

FIG. 9 is a cross-sectional view schematically showing an outline configuration example of the flexible board shown in FIG. 8.

### DETAILED DESCRIPTION OF THE PREFERRED EMBODIMENTS

An embodiment of the present disclosure will hereinafter be described in detail with reference to the drawings. It should be noted that the description will be presented in the following order.
1. Embodiment (an example in which a position of a tip of a reinforcement pattern is located at an inner side of a position of a tip of an electrode terminal)
2. Modified Example (an example in which the position of the tip of the reinforcement pattern coincides with the position of the tip of the electrode terminal)
3. Other Modified Examples

### 1. Embodiment

### Outline Configuration of Printer 5

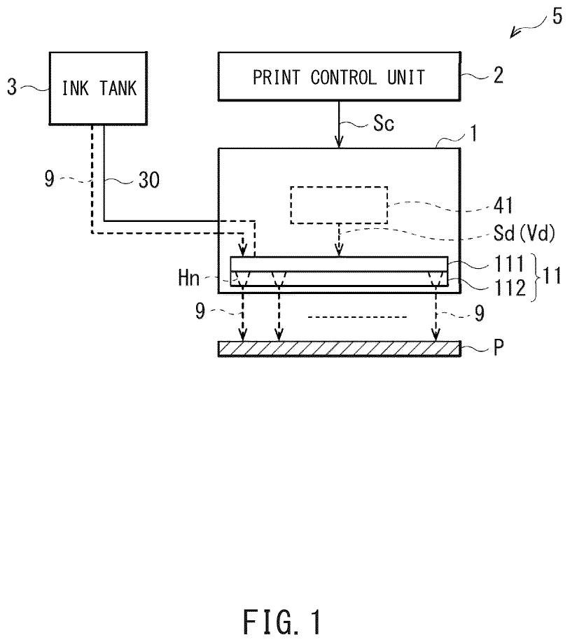

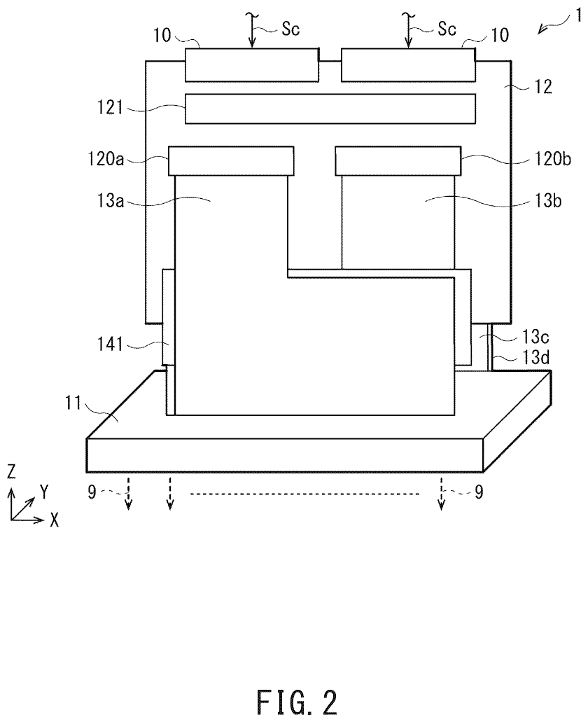

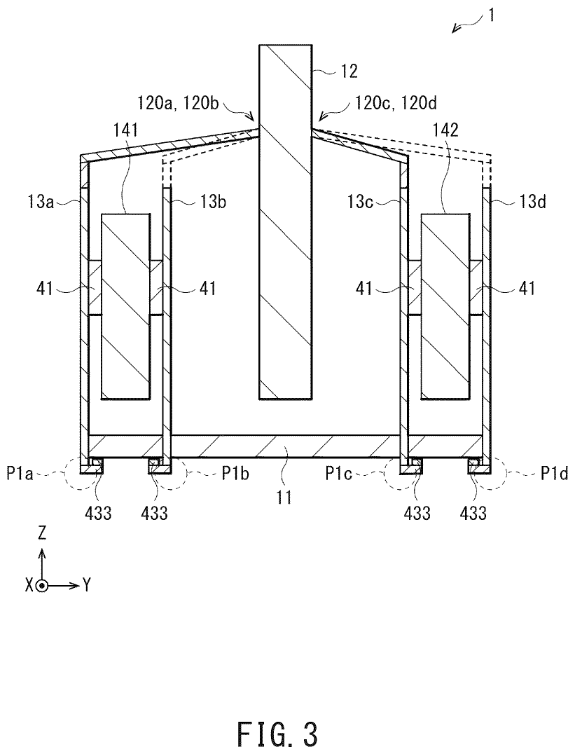

FIG. 1 is a block diagram showing an outline configuration example of a printer 5 as a liquid jet recording apparatus according to an embodiment of the present disclosure. FIG. 2 is a perspective view schematically showing an outline configuration example of an inkjet head 1 as a liquid jet head shown in FIG. 1. FIG. 3 is a cross-sectional view (a Y-Z cross-sectional view) schematically showing a configuration example of the inkjet head 1 shown in FIG. 2. It should be noted that a scale of each of the members is appropriately altered so that the member is shown in a recognizable size in the drawings used in the description of the present specification.

The printer 5 is an inkjet printer that performs recording (printing) of images, characters, and the like on a recording target medium (e.g., recording paper P shown in FIG. 1) using ink 9 described later. As shown in FIG. 1, the printer 5 is provided with the inkjet head 1, a print control unit 2, and an ink tank 3.

It should be noted that the inkjet head 1 corresponds to a specific example of a “liquid jet head” in the present disclosure, and the printer 5 corresponds to a specific example of a “liquid jet recording apparatus” in the present disclosure. Further, the ink 9 corresponds to a specific example of a “liquid” in the present disclosure.

(a. Print Control Unit 2)

The print control unit 2 is for supplying the inkjet head 1 with a variety of types of information (data). Specifically, as shown in FIG. 1, the print control unit 2 is arranged to supply each of elements (drive devices 41 described later and so on) in the inkjet head 1 with a print control signal Sc. It should be noted that the print control signal Sc is arranged to include, for example, image data, an ejection timing signal, and a power-supply voltage for allowing the inkjet head 1 to operate.

### (B. Ink Tank 3)

The ink tank 3 is a tank for containing the ink 9 inside. As shown in FIG. 1, it is arranged that the ink 9 in the ink tank 3 is supplied to the inside (a jet section 11 described later) of the inkjet head 1 via an ink supply tube 30. It should be noted that such an ink supply tube 30 is formed of, for example, a flexible hose having flexibility.

### (C. Inkjet Head 1)

The inkjet head 1 is a head for jetting (ejecting) the ink 9 shaped like a droplet from a plurality of nozzle holes Hn described later to the recording paper P as represented by dotted arrows in FIG. 1 to thereby perform recording of images, characters, and so on. As shown in, for example, FIG. 2 and FIG. 3, the inkjet head 1 is provided with a single jet section 11, a single I/F (interface) board 12, four flexible boards 13a, 13b, 13c, and 13d, and two cooling units 141, 142.

### (C-1. I/F Board 12)

As shown in FIG. 2 and FIG. 3, the I/F board 12 is provided with two connectors 10, four connectors 120a, 120b, 120c, and 120d, and a circuit arrangement area 121.

As shown in FIG. 2, the connectors 10 are each a part (a connector part) for inputting the print control signal Sc which is described above, and which is supplied from the print control unit 2 toward the inkjet head 1 (the flexible boards 13a, 13b, 13c, and 13d described later). The connectors 120a, 120b, 120c, and 120d are parts (connector parts) which electrically couple the I/F board 12 to the flexible boards 13a, 13b, 13c, and 13d, respectively.

The circuit arrangement area 121 is an area where a variety of circuits are arranged on the I/F board 12. It should be noted that it is also possible to arrange that such a circuit arrangement area is also disposed in other areas on the I/F board 12.

### (C-2. Jet Section 11)

As shown in FIG. 1, the jet section 11 is a section which has the plurality of nozzle holes Hn, and which jets the ink 9 from these nozzle holes Hn. It is arranged that such jet of the ink 9 is performed in accordance with drive signals Sd (drive voltages Vd) transmitted from the drive devices 41 described later on each of the flexible boards 13a, 13b, 13c, and 13d (see FIG. 1). It should be noted that the drive signals Sd and the print control signals Sc described above each correspond to a specific example of an “electric signal” in the present disclosure.

As shown in FIG. 1, such a jet section 11 is configured to include an actuator plate 111 and a nozzle plate 112.

### (Nozzle Plate 112)

The nozzle plate 112 is a plate formed of a film material such as polyimide or a metal material, and has the plurality of nozzle holes Hn described above as shown in FIG. 1. These nozzle holes Hn are formed side by side at predetermined intervals, and each has, for example, a circular shape. It should be noted that these nozzle holes Hn each correspond to a specific example of a “nozzle” in the present disclosure.

In the example of the jet section 11 shown in FIG. 2, the jet section 11 is configured with a plurality of nozzle arrays (four nozzle arrays) each of which has the plurality of nozzle holes Hn in the nozzle plate 112 arranged along an array direction (an X-axis direction). Further, these four nozzle arrays are arranged side by side along a direction (a Y-axis direction) perpendicular to the array direction.

### (Actuator Plate 111)

The actuator plate 111 is a plate formed of a piezoelectric material such as PZT (lead zirconate titanate). The actuator plate 111 is provided with a plurality of channels (pressure chambers). These channels are each a part for applying pressure to the ink 9, and are arranged side by side so as to be parallel to each other at predetermined intervals. Each of the channels is partitioned by drive walls (not shown) formed of a piezoelectric body, and forms a groove part having a recessed shape in a cross-sectional view.

As such channels, there exist ejection channels for ejecting the ink 9, and dummy channels (non-ejection channels) which do not eject the ink 9. In other words, it is arranged that the ejection channels are filled with the ink 9 on the one hand, but the dummy channels are not filled with the ink 9 on the other hand. It should be noted that it is arranged that filling of each of the ejection channels with the ink 9 is performed via, for example, a flow channel (a common flow channel) commonly communicated with such ejection channels. Further, it is arranged that each of the ejection channels is individually communicated with the nozzle hole Hn in the nozzle plate 112 on the one hand, but each of the dummy channels is not communicated with the nozzle hole Hn on the other hand. These ejection channels and dummy channels are alternately arranged side by side along the array direction (the X-axis direction) described above.

Further, on the inner side surfaces opposed to each other in the drive walls described above, there are respectively disposed drive electrodes. As the drive electrodes, there exist common electrodes disposed on the inner side surfaces facing the ejection channels, and active electrodes (individual electrodes) disposed on the inner side surfaces facing the dummy channels. These drive electrodes and the drive devices 41 described later are electrically coupled to each other via each of the flexible boards 13a, 13b, 13c, and 13d. Thus, it is arranged that the drive voltages Vd (the drive signals Sd) described above are applied to the drive electrodes from the drive devices 41 via each of the flexible boards 13a, 13b, 13c, and 13d (see FIG. 1).

### (C-3. Flexible Boards 13a, 13b, 13c, and 13d)

The flexible boards 13a, 13b, 13c, and 13d are each a board for electrically coupling the I/F board 12 and the jet section 11 to each other as shown in FIG. 2 and FIG. 3. These flexible boards 13a, 13b, 13c, and 13d are arranged to individually control jet actions of the ink 9 in the four nozzle arrays in the nozzle plate 112 described above, respectively. Further, as indicated by, for example, the reference symbols P1a, P1b, P1c, and P1d in FIG. 3, it is arranged that the flexible boards 13a, 13b, 13c, and 13d are folded around places (around pressure-bonding electrode parts 433) where the flexible boards 13a, 13b, 13c, and 13d are coupled to the jet section 11, respectively. It should be noted that it is arranged that electrical coupling between the pressure-bonding electrode parts 433 and the jet section 11 is achieved by, for example, thermocompression bonding using an ACF (Anisotropic Conductive Film). Further, for example, it is possible to arrange that other flexible boards having only the wiring lines are further ACF-bonded to the flexible boards 13a, 13b, 13c, and 13d, and those other flexible boards and the jet section 11 are ACF-bonded to each other.

On each of such flexible boards 13a, 13b, 13c, and 13d (on a wiring layer at an obverse surface S1 side described later), there is individually mounted the single drive device or a plurality of drive devices 41 (see FIG. 3). These drive devices 41 are each a device for outputting the drive signals Sd (the drive voltages Vd) for jetting the ink 9 from the nozzle holes Hn in the corresponding nozzle array in the jet section 11. Therefore, it is arranged that such drive signals Sd are transmitted from each of the flexible boards 13a, 13b, 13c, and 13d to the jet section 11. It should be noted that such drive devices 41 are each formed of, for example, an ASIC (Application Specific Integrated Circuit).

Further, these drive devices 41 are arranged to be cooled by the cooling units 141, 142 described above. Specifically, as shown in FIG. 3, the cooling unit 141 is fixedly arranged between the drive devices 41 on the flexible boards 13a, 13b, and by pressing the cooling unit 141 against each of these drive devices 41, the drive devices 41 are cooled. Similarly, the cooling unit 142 is fixedly arranged between the drive devices 41 on the flexible boards 13c, 13d, and by pressing the cooling unit 142 against each of these drive devices 41, the drive devices 41 are cooled. It should be noted that such cooling units 141, 142 can each be configured using a variety of types of cooling mechanisms.

### Detailed Configuration of Flexible Boards 13a, 13b, 13c, and 13d

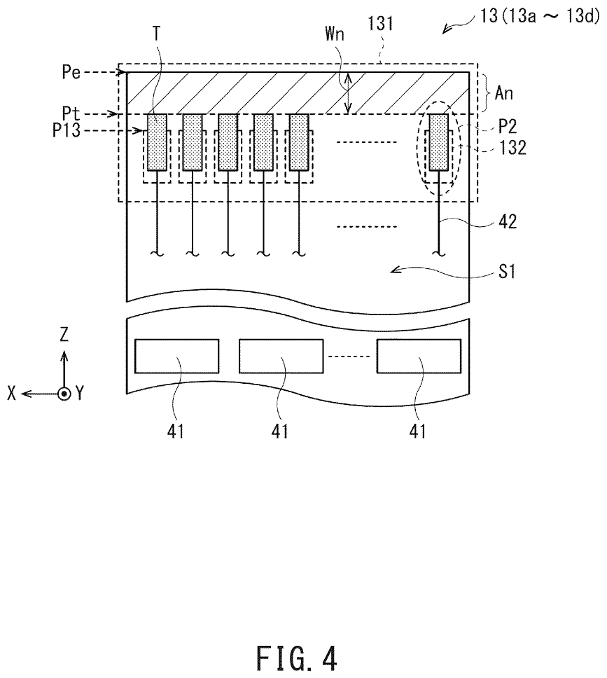

Subsequently, a detailed configuration example of the flexible boards 13a, 13b, 13c, and 13d described above will be described with reference to FIG. 4 to FIG. 6 in addition to FIG. 1 to FIG. 3.

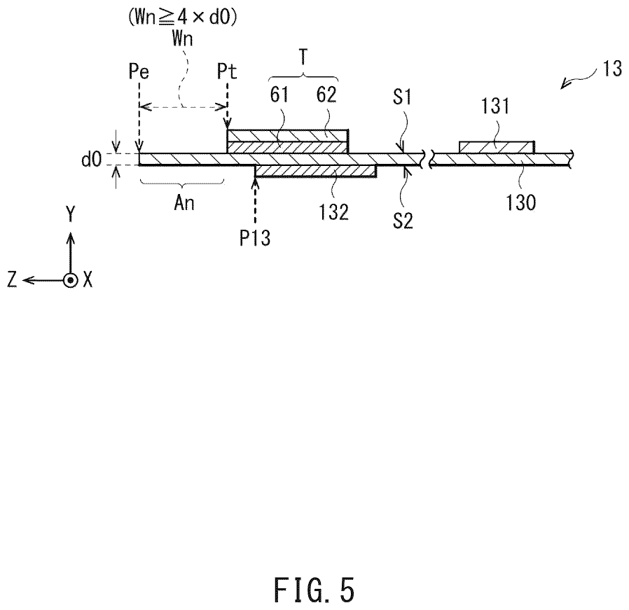

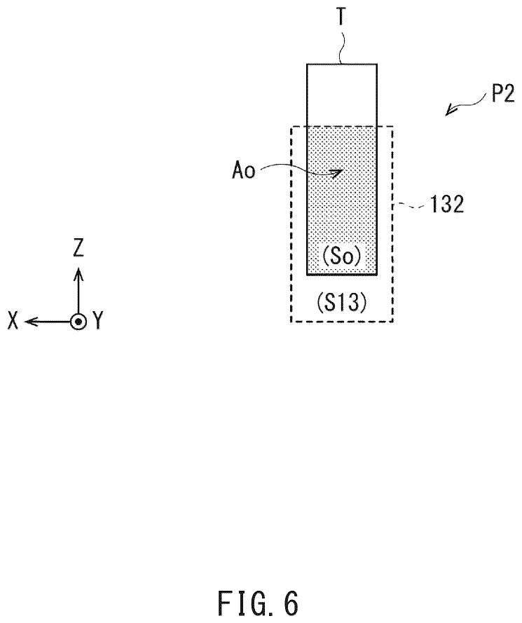

FIG. 4 is a plan view (a Z-X plan view) schematically showing an outline configuration example of the flexible boards 13a to 13d (hereinafter collectively referred to as flexible boards 13 as appropriate) shown in FIG. 2 and FIG. 3. FIG. 5 is a cross-sectional view (a Y-Z cross-sectional view) schematically showing the outline configuration example of the flexible board 13 shown in FIG. 4. FIG. 6 is a plan view (a Z-X plan view) schematically showing, in an enlarged manner, a part (around a portion indicated by a reference symbol P2) of the flexible board 13 shown in FIG. 4.

First, the flexible board 13 is formed as a double-sided board with a multilayered structure including the obverse surface S1 and a reverse surface S2. Specifically, the flexible board 13 has, as wiring layers of such a multilayered structure (a double-layered structure), a first wiring layer at the obverse surface S1 side and a second wiring layer at the reverse surface S2 side opposed to each other along a direction (the Y-axis direction) perpendicular to a board surface (a Z-X plane).

Here, the obverse surface S1 and the reverse surface S2 described above correspond to an example of a “first surface” and a “second surface” in the present disclosure, respectively. It should be noted that it is possible to adopt a structure in which the wiring layers in the flexible board 13 are, for example, three or more layers including the first wiring layer and the second wiring layer described above.

Further, as shown in FIG. 4 to FIG. 6, the flexible board 13 has a base member 130, the single drive device 41 or the plurality of drive devices 41 (the plurality of drive devices 41 in this example) described above, wiring patterns 42, a terminal section 131, and reinforcing patterns 132. It should be noted that the base member 130 is formed of, for example, polyimide (PI) provided with copper foil.

As described above, the drive devices 41 are disposed on the board surface (the obverse surface S1) of the flexible board 13. Further, in the example shown in FIG. 4, the plurality of drive devices 41 is arranged side by side along the X-axis direction on the board surface of the flexible board 13.

As shown in FIG. 4, the wiring patterns 42 are patterns of a variety of wiring lines to electrically be coupled to the drive devices 41. As the wiring patterns 42 there are included, for example, signal wiring patterns corresponding to wiring lines of a variety of signals, power supply wiring patterns corresponding to wiring lines of a variety of power supplies, and ground wiring patterns corresponding to the ground wiring lines.

The terminal section 131 is arranged in an end region at the pressure-bonding electrode parts 433 side (the jet section 11 side) or an end region at the I/F board 12 side on the board surface of the flexible board 13 (see FIG. 4). This terminal section 131 includes the flexible board 13 and a single electrode terminal T or a plurality of electrode terminals T (the plurality of electrode terminals T in this example) which is a section for electrically coupling the flexible board 13 and the pressure-bonding electrode part 433 (the jet section 11) or the I/F board 12 to each other. In other words, this terminal section 131 is a section to electrically be coupled to the jet section 11 (another member) via the pressure-bonding electrode parts 433 with thermocompression bonding using the ACF described above, or a section to be inserted in the connectors 120a to 120d on the I/F board 12 as another member. It should be noted that it is possible to arrange that, for example, the flexible boards 13 and the I/F board 12 are electrically coupled to each other with thermocompression bonding using the ACF described above instead of being electrically coupled to each other using such connectors 120a to 120d.

As shown in FIG. 4 and FIG. 5, the electrode terminals T are disposed on the obverse surface S1 of/on the board surfaces of the flexible board 13. Further, as shown in FIG. 5, the electrode terminals T have a multilayered structure (a double-layered structure in this example) configured to include an electrode layer 61 disposed on the board surface (the obverse surface S1) and a plated layer 62 covering this electrode layer 61. The electrode layer 61 is configured using an electrically-conductive material such as copper (Cu). Further, the plated layer 62 is configured using a single layer structure or a multilayer structure using an electrically-conductive material such as gold (Au), nickel (Ni), or palladium (Pd). Specifically, the plated layer 62 is configured using, for example, a single layer structure of gold, or a multilayer structure of gold and one of nickel and palladium.

Here, in the flexible board 13 in the present embodiment, as shown in FIG. 4 and FIG. 5, the electrode terminals T in the terminal section 131 are arranged at a distance from an outer shape position Pe of the board surface via a non-electrode region An. It should be noted that the non-electrode region An is a region in which the electrode terminals T are not disposed in the terminal section 131, and is arranged along the X-axis direction between the outer shape position Pe of the flexible board 13 and a tip position Pt at the outer shape position Pe side in the electrode terminal T (see FIG. 4 and FIG. 5). Further, a width Wn (a distance in the Z-axis direction from the outer shape position Pe to the tip position Pt described above) of the non-electrode region An is set to have, for example, a value (Wn≥4×d0) no smaller than four times a thickness d0 (e.g., a thickness of PI) of the base member 130 in the flexible board 13 (see FIG. 5).

The reinforcing patterns 132 are each disposed on the reverse surface S2 of/on the board surfaces of the flexible board 13 as shown in FIG. 5, and are patterns for suppressing a deformation in the thickness direction (the Y-axis direction) in the electrode terminal T. Specifically, the reinforcing patterns 132 are arranged to suppress the deformation in the thickness direction of the electrode terminals T when, for example, manufacturing the flexible board 13 (e.g., when cutting an outer shape of the board using a metal mold).

These reinforcing patterns 132 are patterns individually disposed so as to correspond respectively to the electrode terminals T in the example shown in FIG. 4. Further, in the present embodiment, a tip position P13 at the outer shape position Pe side in the reinforcing pattern 132 is located at an opposite side (at an inner side) to the outer shape position Pe with reference to the tip position Pt at the outer shape position Pe side in the electrode terminal T (see FIG. 4 and FIG. 5). Further, as shown in FIG. 6, an arrangement region on the reverse surface S2 in the reinforcing pattern 132 is made larger than an overlapping region Ao in plan view with an arrangement region on the obverse surface S1 in the electrode terminal T. However, for example, the arrangement region on the reverse surface S2 in the reinforcing pattern 132 may be equal to the overlapping region Ao in plan view with the arrangement region on the obverse surface S1 in the electrode terminal T. That is, the area S13 of the arrangement region of the reinforcing pattern 132 is made to have a value no smaller than the area So of this overlapping region Ao ((the area S13)≥(the area So)).

### Operations, and Functions and Advantages

### (A. Basic Operation of Printer 5)

In this printer 5, a recording operation (a printing operation) of images, characters, and so on to the recording target medium (the recording paper P and so on) is performed using such a jet operation of the ink 9 by the inkjet head 1 as described below. Specifically, in the inkjet head 1 according to the present embodiment, the jet operation of the ink 9 using a shear mode is performed in the following manner.

First, the drive devices 41 on each of the flexible boards 13 (13a, 13b, 13c, and 13d) each apply the drive voltages Vd (the drive signals Sd) to the drive electrodes (the common electrodes and the active electrodes) described above in the actuator plate 111 in the jet section 11. Specifically, each of the drive devices 41 applies the drive voltage Vd to the drive electrodes disposed on the pair of drive walls partitioning the ejection channel described above. Thus, the pair of drive walls each deform so as to protrude toward the dummy channel adjacent to the ejection channel.

On this occasion, it results in that the drive wall makes a flexion deformation to have a V shape centering on an intermediate position in the depth direction in the drive wall. Further, due to such a flexion deformation of the drive wall, the ejection channel deforms as if the ejection channel bulges. As described above, due to the flexion deformation caused by a piezoelectric thickness-shear effect in the pair of drive walls, the volume of the ejection channel increases. Further, by the volume of the ejection channel increasing, the ink 9 is induced into the ejection channel as a result.

Subsequently, the ink 9 induced into the ejection channel in such a manner turns to a pressure wave to propagate to the inside of the ejection channel. Then, the drive voltage Vd to be applied to the drive electrodes becomes 0 (zero) V at a timing at which the pressure wave has reached the nozzle hole Hn of the nozzle plate 112 (or a timing around that timing). Thus, the drive walls are restored from the state of the flexion deformation described above, and as a result, the volume of the ejection channel having once increased is restored again.

In such a manner, the pressure inside the ejection channel increases in the process that the volume of the ejection channel is restored, and thus, the ink 9 in the ejection channel is pressurized. As a result, the ink 9 shaped like a droplet is ejected toward the outside (toward the recording paper P) through the nozzle hole Hn (see FIG. 1). The jet operation (the ejection operation) of the ink 9 in the inkjet head 1 is performed in such a manner, and as a result, the recording operation of images, characters, and so on to the recording paper P is performed.

### (B. Functions and Advantages in Inkjet Head 1)

Then, functions and advantages in the inkjet head 1 according to the present embodiment will be described in detail in comparison with a comparative example.

### (B-1. Comparative Example)

First, electric circuit boards used in a related-art inkjet head are arranged to electrically be coupled to each other using connector coupling or the ACF coupling described above. As these electric circuit boards, flexible boards are used in some cases in view of a degree of freedom of an arrangement and a shape, and electrode terminals for transmitting a variety of electric signals are disposed in a coupling section in at least the electric circuit board to be coupled. Further, taking workability and a degree of design freedom into consideration, these electrode terminals are arranged in an end region of the board in many cases, and in order to ensure the coupling reliability, a structure (a multilayered structure) in which Cu patterns are plated with gold is used as the structure of the electrode terminals in many cases. Further, when mass-producing the flexible board, a manufacturing method in which the outer shape of the board is cut using a metal mold is adopted in many cases.

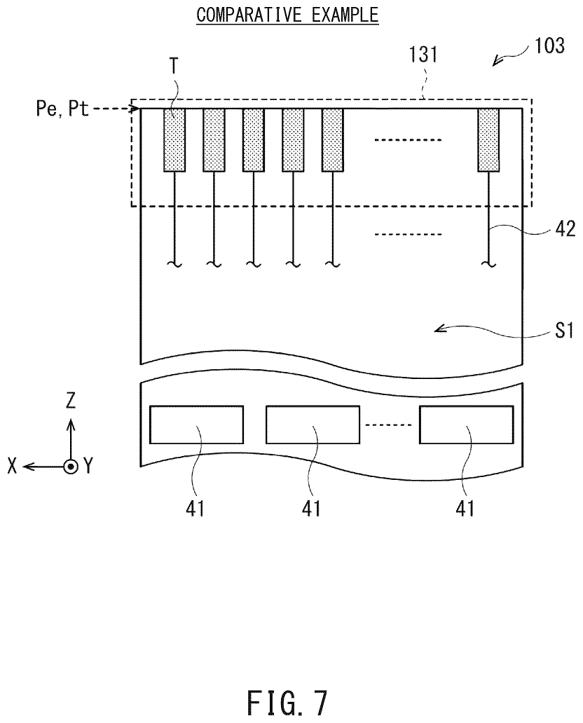

Here, FIG. 7 is a plan view (a Z-X plan view) schematically showing a configuration example of a flexible board (a flexible board 103) related to the comparative example. In the flexible board 103 in the comparative example shown in FIG. 7, unlike the flexible board 13 (see FIG. 4 and FIG. 5) of the present embodiment described above, the electrode terminals T are arranged to extend up to the outer shape position Pe of the board surface. That is, unlike the flexible board 13, in the flexible board 103, the outer shape position Pe of the flexible board 103 and the tip position Pt at the outer shape position Pe side in the electrode terminal T coincide with each other (are aligned with each other) along the Z-axis direction.

However, in the flexible board 103 having such a configuration, a crack becomes likely to occur in the electrode terminal T due to the stress applied during the manufacture (e.g., when cutting the outside shape of the board using the metal mold described above). Further, in this flexible board 103, there is a concern that corrosion may occur in the electrode terminal T due to contamination in the crack generated in the electrode terminal T on, for example, the following grounds.

Specifically, first, when the electrode terminals T have, for example, the multilayered structure described above, since the crack occurs only in the plated layer on the surface in many cases, the electric conduction in the Cu pattern is ensured, and therefore, a failure is unlikely to occur. However, even in that case, when a substance which corrodes the Cu pattern adheres to the crack portion when manufacturing or storing the flexible board 103, there is a concern that the Cu pattern located inside may be corroded. Further, when the flexible board 103 is used in an inkjet head, the electrode terminal is contaminated through the crack due to the adhesion of the ink or the ink atmosphere, and the risk of an occurrence of the corrosion increases. In that case, there is a risk that a contact failure in the electrode terminal occurs due to the corrosion to make it unachievable to ensure the print quality even though no broken line occurs in the electrode terminal.

In this way, in the flexible board 103 in the comparative example, a yield ratio in the manufacture deteriorates, and the contact failure in the electrode terminals T increases, and as a result, it is difficult to improve the reliability while reducing the manufacturing cost.

### (B-2. Functions and Advantages)

In contrast, in the inkjet head 1 according to the present embodiment, since the flexible board 13 is provided with the following configuration, it is possible to obtain, for example, the following functions and advantages.

That is, first, in the flexible board 13 of the present embodiment, the electrode terminals T are arranged at a distance from the outer shape position Pe of the board surface via the non-electrode region An in the end region of the board surface on which the terminal section 131 is disposed. Thus, the occurrence of the crack in the electrode terminal T due to the stress applied during the manufacture (e.g., when cutting the outer shape of the board using the metal mold) and occurrence of the corrosion of the electrode terminal T due to the contamination in the crack portion are reduced. Therefore, the yield ratio when manufacturing the flexible board 13 is improved, and the contact failure in the electrode terminal T is reduced, and as a result, in the present embodiment, it becomes possible to improve the reliability while reducing the manufacturing cost compared to the comparative example described above and so on.

Further, in the present embodiment, since the electrode terminals T are arranged on the obverse surface S1 as the board surfaces, and the reinforcing patterns 132 are arranged on the reverse surface S2 as the board surface, the following is achieved. That is, since such reinforcing patterns 132 are provided, deformation in the thickness direction (the Y-axis direction) in the electrode terminals T is suppressed, and therefore, it becomes possible to further improve the reliability in the flexible board 13.

Further, in the present embodiment, since the tip position P13 at the outer shape position Pe side in the reinforcing pattern 132 is located at the opposite side (at the inner side) to the outer shape position Pe with reference to the tip position Pt at the outer shape position Pe side in the electrode terminal T, the following is achieved. That is, due to the reinforcing patterns 132, it becomes easy to confirm the positions of the electrode terminals T when electrically coupling the flexible board 13 and the I/F board 12 to each other (it becomes easy to use the reinforcing patterns 132 as marks when performing the electrical coupling) while suppressing the deformation in the thickness direction in the electrode terminals T. As a result, it becomes possible to easily improve the reliability in the flexible board 13.

In addition, in the present embodiment, since the area S13 of the arrangement region on the reverse surface S2 in the reinforcing pattern 132 has the value no smaller than the area So of the overlapping region Ao in the plan view with the arrangement region on the obverse surface S1 in the electrode terminal T ((the area S13)≥(the area So)), the following is achieved. That is, it becomes easy to exert the function of the reinforcing patterns 132 suppressing the deformation in the thickness direction of the electrode terminals T, and as a result, it becomes possible to further improve the reliability in the flexible board 13.

### 2. Modified Example

Then, a modified example of the embodiment described above will be described. It should be noted that hereinafter, the same elements as those in the embodiment are denoted by the same reference symbols, and the description thereof will be omitted as appropriate.

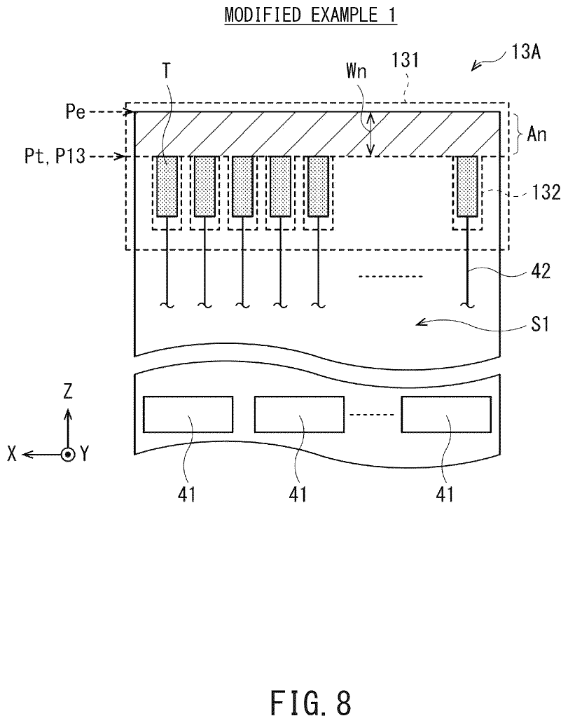

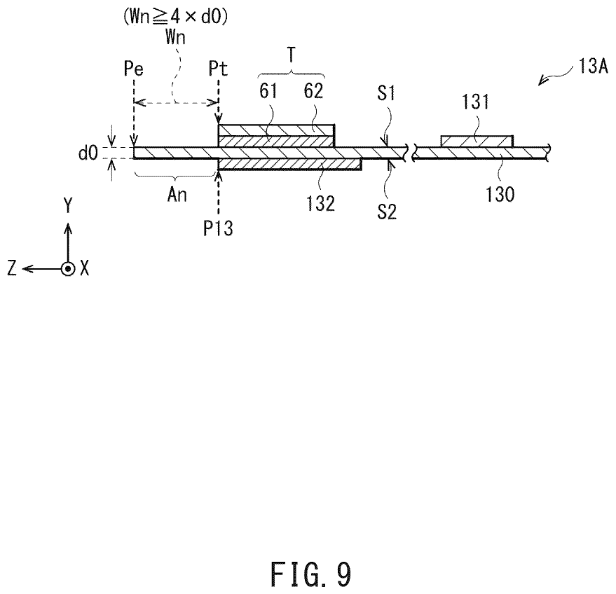

FIG. 8 is a plan view (a Z-X plan view) schematically showing an outline configuration example of a flexible board (a flexible board 13A) related to the modified example. FIG. 9 is a cross-sectional view (a Y-Z cross-sectional view) schematically showing the outline configuration example of the flexible board 13A shown in FIG. 8.

The flexible board 13A of this modified example corresponds to what is obtained by changing the tip position P13 at the outer shape position Pe side in the reinforcing pattern 132 in the flexible board 13 (FIG. 4 and FIG. 5) described in the embodiment, and the rest of the configuration is made basically the same.

Specifically, in the flexible board 13, as described above, the tip position P13 at the outer shape position Pe side in the reinforcing pattern 132 is located at the opposite side (at the inner side) to the outer shape position Pe with reference to the tip position Pt at the outer shape position Pe side in the electrode terminal T. In contrast, in the flexible board 13A, as shown in FIG. 8 and FIG. 9, the tip position P13 at the outer shape position Pe side in the reinforcing pattern 132 is located at the same position with reference to the tip position Pt at the outer shape position Pe side in the electrode terminal T. That is, in this flexible board 13A, the tip position P13 in the reinforcing pattern 132 and the tip position Pt in the electrode terminal T coincide with each other (are aligned with each other) along the Z-axis direction.

It should be noted that also in this flexible board 13A, similarly to the flexible board 13, the arrangement region on the reverse surface S2 in the reinforcing pattern 132 is made larger than the overlapping region Ao in plan view with the arrangement region on the obverse surface S1 in the electrode terminal T ((the area S13)>(the area So)).

Also in the modified example having such a configuration, it is possible to obtain substantially the same advantages due to basically the same function as that of the embodiment.

### 3. Other Modified Examples

The present disclosure is described hereinabove citing the embodiment and the modified example, but the present disclosure is not limited to the embodiment and so on, and a variety of modifications can be adopted.

For example, in the embodiment and so on described above, the description is presented specifically citing the configuration examples (the shapes, the arrangements, the number and so on) of each of the members in the printer and the inkjet head, but those described in the above embodiment and so on are not limitations, and it is possible to adopt other shapes, arrangements, numbers and so on. Further, the values or the ranges, the magnitude relation and so on of a variety of parameters described in the above embodiments are not limited to those described in the above embodiments, but can also be other values or ranges, other magnitude relations and so on.

Specifically, for example, in the embodiment and so on described above, the description is presented specifically citing the configuration examples (the shapes, the arrangement, the number, and so on) of the flexible boards, the drive devices, a variety of wiring patterns, and so on, but these configuration examples are not limited to those described in the above embodiment and so on. For example, in the embodiment and so on described above, there is described the example when the plurality of drive boards is disposed inside the inkjet head, but this example is not a limitation, and it is possible to arrange that, for example, just one drive board is disposed alone inside the inkjet head. Further, in the embodiment and so on described above, the description is presented specifically citing the shape (the layer structure), the arrangement, the number, and so on of the electrode terminals, but this example is not a limitation, and for example, the electrode terminal may have a single layer structure, or other arrangement position may be adopted. Further, in the embodiment and so on described above, an example of the case in which the reinforcing patterns are disposed on the flexible board is described, but it is possible to arrange that, for example, such reinforcing patterns are not disposed on the flexible board. It should be noted that the shape, the arrangement, the number, and so on of the reinforcing patterns are not limited to the example cited in the embodiment and so on described above. Further, in the embodiment and so on described above, there is described the example when the plurality of drive devices is disposed on the drive board, but this example is not a limitation, and it is possible to arrange that, for example, just one drive device is disposed on the drive board or that no drive device is disposed on the drive board. Further, in the embodiment and so on described above, the shape of the drive device is assumed to be the rectangular shape, but this example is not a limitation, and the shape of the drive device can be, for example, a square shape.

Further, a variety of types of structures can be adopted as the structure of the inkjet head. Specifically, for example, it is possible to adopt a so-called side-shoot type inkjet head which emits the ink 9 from a central portion in the extending direction of each of the ejection channels in the actuator plate 111. Alternatively, it is possible to adopt, for example, a so-called edge-shoot type inkjet head for ejecting the ink 9 along the extending direction of each of the ejection channels. Further, the type of the printer is not limited to the type described in the above embodiment and so on, and it is possible to apply a variety of types such as a MEMS (Micro Electro-Mechanical Systems) type.

Further, for example, it is possible to apply the present disclosure to either of an inkjet head of a circulation type which uses the ink 9 while circulating the ink 9 between the ink tank and the inkjet head, and an inkjet head of a non-circulation type which uses the ink 9 without circulating the ink 9.

Further, the series of processing described in the above embodiments and so on can be arranged to be performed by hardware (a circuit), or can also be arranged to be performed by software (a program). When it is arranged that the series of processing is performed by the software, the software is constituted by a program group for making the computer perform the functions. The programs can be incorporated in advance in the computer described above to be used by the computer, for example, or can also be installed in the computer described above from a network or a recording medium to be used by the computer.

Further, in the embodiment and so on described above, the description is presented citing the printer 5 (the inkjet printer) as a specific example of the “liquid jet recording apparatus” in the present disclosure, but this example is not a limitation, and it is also possible to apply the present disclosure to apparatuses other than the inkjet printer. In other words, it is also possible to arrange that the “liquid jet head” (the inkjet head) of the present disclosure is applied to apparatuses other than the inkjet printer. Specifically, it is also possible to arrange that the “liquid jet head” of the present disclosure is applied to an apparatus such as a facsimile or an on-demand printer.

In addition, it is also possible to apply the variety of examples described hereinabove in arbitrary combination.

It should be noted that the advantages described in the present specification are illustrative only, and are not a limitation, and other advantages can also be provided.

Further, the present disclosure can also take the following configurations.

### (1)

A flexible board configured to transmit electric signals to be applied to a liquid jet head having a plurality of nozzles, including
a terminal section disposed in an end region on a board surface, and including a single electrode terminal or a plurality of electrode terminals as a part to electrically be coupled to another member, wherein
the electrode terminal is disposed in the end region at a distance from an outer shape position of the board surface via a non-electrode region.

### (2)

The flexible board according to (1) described above, wherein
the electrode terminal is configured to include
an electrode layer disposed on the board surface, and
a plated layer covering the electrode layer.

### (3)

The flexible board according to (1) or (2) described above, wherein
a width of the non-electrode region corresponding to a distance from the outer shape position to the electrode terminal has a value no smaller than four times a thickness of a base member in the flexible board.

### (4)

The flexible board according to any one of (1) to (3) described above, wherein
the electrode terminal is disposed on a first surface of/on the board surfaces, and
a reinforcing pattern configured to suppress a deformation in a thickness direction in the electrode terminal is disposed on a second surface opposed to the first surface of/on the board surfaces.

### (5)

The flexible board according to (4) described above, wherein
a tip at the outer shape position side in the reinforcing pattern is located at a same position or at an inner side which is an opposite side to the outer shape position with reference to a tip at the outer shape position side in the electrode terminal.

### (6)

The flexible board according to (4) or (5) described above, wherein
an area of an arrangement region on the second surface in the reinforcing pattern has a value no smaller than an area of an overlapping region in plan view with an arrangement region on the first surface in the electrode terminal.

### (7)

The flexible board according to any one of (1) to (6) described above, further including
a single drive device or a plurality of drive devices which are disposed on the board surface, and which is configured to generate drive signals which are the electric signals configured to jet a liquid from the nozzles.

### (8)

A liquid jet head including
the flexible board according to any one of (1) to (7) described above, and
a jet section which is configured to jet the liquid based on the electric signals transmitted from the flexible board, and which includes the plurality of nozzles.

### (9)

A liquid jet recording apparatus including
the liquid jet head according to (8) described above.

What is claimed is:

1. A flexible board configured to transmit electric signals to be applied to a liquid jet head having a plurality of nozzles, comprising
a terminal section disposed in an end region on a board surface, and including a single electrode terminal or a plurality of electrode terminals as a part to electrically be coupled to another member, wherein
the electrode terminal is disposed in the end region at a distance from an outer shape position of the board surface via a non-electrode region.

2. The flexible board according to claim 1, wherein
the electrode terminal is configured to include
an electrode layer disposed on the board surface, and
a plated layer covering the electrode layer.

3. The flexible board according to claim 1, wherein
a width of the non-electrode region corresponding to a distance from the outer shape position to the electrode terminal has a value no smaller than four times a thickness of a base member in the flexible board.

4. The flexible board according to claim 1, wherein
the electrode terminal is disposed on a first surface of/on the board surfaces, and
a reinforcing pattern configured to suppress a deformation in a thickness direction in the electrode terminal is disposed on a second surface opposed to the first surface of/on the board surfaces.

5. The flexible board according to claim 4, wherein
a tip at the outer shape position side in the reinforcing pattern is located at a same position or at an inner side which is an opposite side to the outer shape position with reference to a tip at the outer shape position side in the electrode terminal.

6. The flexible board according to claim 4, wherein
an area of an arrangement region on the second surface in the reinforcing pattern has a value no smaller than an area of an overlapping region in plan view with an arrangement region on the first surface in the electrode terminal.

7. The flexible board according to claim 1, further comprising
a single drive device or a plurality of drive devices which are disposed on the board surface, and which is configured to generate drive signals which are the electric signals configured to jet a liquid from the nozzles.

8. A liquid jet head comprising:
the flexible board according to claim 1; and
a jet section which is configured to jet the liquid based on the electric signals transmitted from the flexible board, and which includes the plurality of nozzles.

9. A liquid jet recording apparatus comprising
the liquid jet head according to claim 8.
